(19) United States
(12) Patent Application Publication
(10) Pub. No.: US 2025/0348232 A1
(43) Pub. Date: Nov. 13, 2025

(54) SEMICONDUCTOR DEVICE, SEMICONDUCTOR SYSTEM, AND OPERATING METHODS OF THE SEMICONDUCTOR DEVICE AND THE SEMICONDUCTOR SYSTEM

(71) Applicant: SK hynix Inc., Icheon-si (KR)

(72) Inventors: Seung Yun LEE, Icheon-si (KR); Taek Seung KIM, Icheon-si (KR)

(21) Appl. No.: 19/025,518

(22) Filed: Jan. 16, 2025

(30) Foreign Application Priority Data
May 7, 2024 (KR) 10-2024-0059870

(51) Int. Cl. G06F 3/06

(52) U.S. Cl. CPC G06F 3/0619; G06F 3/0659; G06F 3/0679

(57) ABSTRACT

An operating method of a semiconductor device may include checking an operation time stamp when receiving a read command, calculating an elapsed time based on the operation time stamp that has been stored and a time when the read command has been received, comparing the elapsed time and a first setting time, selecting a read voltage having a first level instead of a target level when the elapsed time is greater than the first setting time, and performing a read operation based on the read voltage that has been selected.

### CROSS-REFERENCE TO RELATED APPLICATION

This application claims priority under 35 U.S.C. § 119(a) to Korean Patent Application No. 10-2024-0059870, filed in the Korean Intellectual Property Office on May 7, 2024, the entire contents of which are incorporated herein by reference.

### BACKGROUND

### 1. Technical Field

Embodiments of the present disclosure relate to integrated circuit technology and, more particularly, to a semiconductor device and system designed to minimize read disturbance, and operating methods of the semiconductor device and the semiconductor system.

### 2. Related Art

Recently, as an electronic device is reduced in size, has lower power consumption and higher performance, and is diversified, a semiconductor device capable of storing information is required for various electronic devices, such as computers and portable communication devices. Accordingly, a semiconductor device capable of storing data by using a characteristic in which the semiconductor device switches between different resistance states depending on a voltage or current applied thereto is researched. Such a semiconductor device includes resistive random access memory (RRAM), phase change random access memory (PRAM), ferroelectric random access memory (FRAM), magnetic random access memory (MRAM), and an E-fuse.

### SUMMARY

In an embodiment, an operating method of a semiconductor device may include checking an operation time stamp when receiving a read command, calculating an elapsed time based on the operation time stamp that has been stored and a time when the read command has been received, comparing the elapsed time and a first setting time, selecting a read voltage having a first level instead of a target level when the elapsed time is greater than the first setting time, and performing a read operation based on the read voltage that has been selected.

In an embodiment, a semiconductor device may include a memory area including a plurality of memory cells and control logic configured to perform a write operation of storing data in the memory area or a read operation of outputting data stored in the memory area, based on a command. Times when the write operation and the read operation were performed may be stored in a specific area of the memory area under the control of the control logic.

In an embodiment, a semiconductor system may include a controller configured to provide a read command or a write command based on a request from a host, buffer memory configured to store a time when the read command or the write command is provided and configured to provide the stored time to the controller when receiving the read command, and a semiconductor device configured to store data or output data that have been stored in the semiconductor device, based on the read command or the write command.

### BRIEF DESCRIPTION OF THE DRAWINGS

FIG. 1 illustrates a semiconductor system according to an embodiment of the present disclosure.

FIG. 2 illustrates a semiconductor system according to another embodiment of the present disclosure.

FIGS. 3 and 4 describe operations of a semiconductor device and a semiconductor system according to embodiments of the present disclosure.

FIG. 5 is a flowchart describing an operating method of a semiconductor system or a semiconductor device according to an embodiment of the present disclosure.

### DETAILED DESCRIPTION

Hereinafter, embodiments according to the technical spirit of the present disclosure are described with reference to the accompanying drawings.

Embodiments provide a semiconductor device and system that control a level of a read voltage based on an elapsed time up to a read operation after a write operation and/or an elapsed time up to a current read operation after a previous read operation, and operating methods of the semiconductor device and system.

In accordance with the embodiments, it is possible to improve the reliability of a memory cell by minimizing read disturbance in a set state and a reset state.

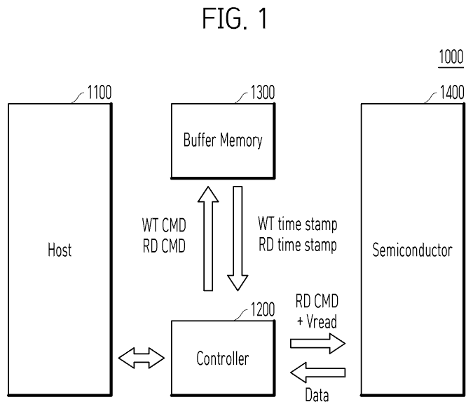

FIG. 1 illustrates a semiconductor system 1000 according to an embodiment of the present disclosure.

Referring to FIG. 1, the semiconductor system 1000 includes a host 1100, a controller 1200, a buffer memory 1300, and a semiconductor device 1400.

In an embodiment, the host 1100 includes at least one operating system (OS) or a plurality of operating systems, and transmits, to the controller 1200, a plurality of commands corresponding to a user's request. Furthermore, the host 1100 receives pieces of information corresponding to a user's request from the controller 1200.

The controller 1200 controls the semiconductor device 1400 based on commands of the host 1100. For example, the controller 1200 stores, in the semiconductor device 1400, data provided by the host 1100, and provides the host 1100 with data that have been stored in the semiconductor device 1400. In this case, when the controller 1200 stores data in the semiconductor device 1400, the controller 1200 provides a write command WT CMD to the semiconductor device 1400. Furthermore, when the controller 1200 transmits, to the host 1100, data that have been stored in the semiconductor device 1400, the controller 1200 provides a read command RD CMD to the semiconductor device 1400. When the controller 1200 provides the write command WT CMD to the semiconductor device 1400, the controller 1200 may also provide the write command WT CMD to the buffer memory 1300. When the controller 1200 provides the read command RD CMD to the semiconductor device 1400, the controller 1200 may also provide the read command RD CMD to the buffer memory 1300.

When the controller 1200 provides the read command RD CMD to the semiconductor device 1400, the controller 1200 determines a level of a read voltage Vread based on a write time stamp (WT time stamp) and a read time stamp (RD time stamp), and transmits, to the semiconductor device 1400, information regarding the level of the read voltage Vread that has been determined.

In an embodiment, the controller 1200 generates information regarding the level of the read voltage Vread, which has been adjusted based on an elapsed time between the issuance of the write command WT CMD and the issuance of the read command RD CMD, using the write time stamp (WT time stamp). This information is provided to the semiconductor device 1400. The issuance of the write command WT CMD and the issuance of the read command RD CMD occur when these commands are provided to the semiconductor device 1400.

In this embodiment, when the elapsed time is determined to be equal to or smaller than a critical time, the controller 1200 determines the level of the read voltage Vread as a target level. On the other hand, when the elapsed time is determined to exceed the critical time, the controller 1200 determines the level of the read voltage Vread as a level higher than the target level.

In another embodiment, the controller 1200 determines the level of the read voltage Vread based on the read time stamp (RD time stamp), and transmits, to the semiconductor device 1400, information regarding the level of the read voltage Vread that has been determined. For example, the controller 1200 generates information regarding the level of the read voltage Vread that has been adjusted based on an elapsed time between the issuance of a current read command RD CMD and the issuance of a previous read command RD CMD using the read time stamp (RD time stamp). This information is provided to the semiconductor device 1400.

In the other embodiment, when the elapsed time is determined to be equal to or smaller than a critical time, the controller 1200 determines the level of the read voltage Vread as a target level. On the other hand, when the elapsed time is determined to exceed the critical time, the controller 1200 determines the level of the read voltage Vread as a level higher than the target level.

As described above, when the controller 1200 provides the read command RD CMD to the semiconductor device 1400, the controller 1200 determines the level of the read voltage Vread based on the write time stamp (WT time stamp) or the read time stamp (RD time stamp), and transmits, to the semiconductor device 1400, information regarding the level of the read voltage Vread that has been determined.

When the controller 1200 provides the write command WT CMD or the read command RD CMD to the semiconductor device 1400, the buffer memory 1300 also receives the write command WT CMD or the read command RD CMD from the controller 1200. In this case, the buffer memory 1300 stores the time when the write command WT CMD is received as the write time stamp (WT time stamp). The buffer memory 1300 stores the time when the read command RD CMD is received as the read time stamp (RD time stamp). As a result, the buffer memory 1300 stores the time when the controller 1200 provides the write command WT CMD to the semiconductor device 1400 as the write time stamp (WT time stamp). Furthermore, the buffer memory 1300 stores the time when the controller 1200 provides the read command RD CMD to the semiconductor device 1400 as the read time stamp (RD time stamp). When receiving the read command RD CMD, the buffer memory 1300 provides the controller 1200 with the write time stamp (WT time stamp) and the read time stamp (RD time stamp) that have been stored in the buffer memory 1300.

When the semiconductor device 1400 receives the write command WT CMD or the read command RD CMD from the controller 1200, it transmits or receives data Data to and from the controller 1200 depending on the type of command that is received. For example, when receiving the write command WT CMD and the data Data from the controller 1200, the semiconductor device 1400 stores the data Data therein. On the other hand, when receiving the read command RD CMD from the controller 1200, the semiconductor device 1400 transmits, to the controller 1200, the data Data that have been stored therein.

The semiconductor device 1400 includes a memory area including a plurality of memory cells, and stores the data Data in the plurality of memory cells. When receiving the write command WT CMD, the semiconductor device 1400 performs a write operation for transitioning a state of a memory cell to one of a plurality of states based on a value of the data Data. When receiving the read command RD CMD, the semiconductor device 1400 determines the state of the memory cell, and transmits, to the controller 1200, the data Data corresponding to the determined state.

For example, the semiconductor device 1400 performs a write operation for transitioning a state of a memory cell into one of a set state and a reset state based on the value of the data Data that is received from the controller 1200. After that, when receiving the read command RD CMD, the semiconductor device 1400 determines whether the state of the memory cell is the set state or the reset state, and transmits, to the controller 1200, the data Data corresponding to the determined state. In this case, the read voltage Vread may be a voltage that determines whether the state of the memory cell is the set state or the reset state. The write time stamp (WT time stamp) or the read time stamp (RD time stamp) may be stored for each address of a write operation or a read operation, respectively. Accordingly, the aforementioned operation of the semiconductor system 1000 may occur when a write operation and a read operation, or a previous read operation and a current read operation, are performed based on the same address.

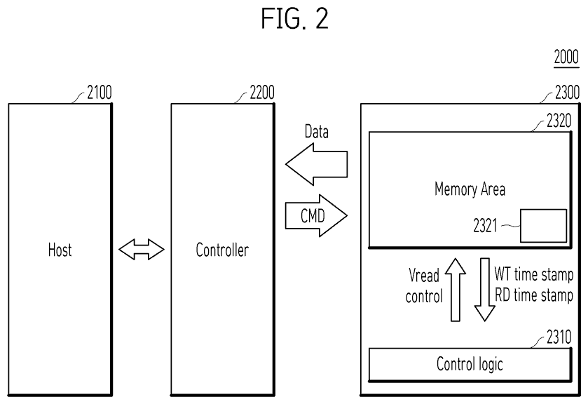

FIG. 2 illustrates a semiconductor system 2000 according to another embodiment of the present disclosure.

Referring to FIG. 2, the semiconductor system 2000 includes a host 2100, a controller 2200, and a semiconductor device 2300.

In an embodiment, the host 2100 includes at least one operating system (OS) or a plurality of operating systems, and transmits, to the controller 2200, a plurality of commands corresponding to a user's request. Furthermore, the host 2100 receives, from the controller 2200, pieces of information corresponding to a user's request.

The controller 2200 controls the semiconductor device 2300 based on commands of the host 2100. For example, the controller 2200 stores data provided by the host 2100 in the semiconductor device 2300, and provides the host 2100 with data stored in the semiconductor device 2300. In this case, when the controller 2200 stores data in the semiconductor device 2300, the controller 2200 provides a write command WT CMD to the semiconductor device 2300. Furthermore, when the controller 2200 transmits data stored in the semiconductor device 2300 to the host 2100, the controller 2200 provides a read command RD CMD to the semiconductor device 2300. In this case, the command CMD provided from the controller 2200 to the semiconductor device 2300 may vary, but the write command WT CMD and the read command RD CMD are described as examples for convenience of description. The present disclosure is not limited to these commands.

When the semiconductor device 2300 receives the write command WT CMD and the read command RD CMD from the controller 2200, it transmits and receives data Data to and from the controller 2200 depending on the type of command that is received. For example, when the semiconductor device 2300 receives the write command WT CMD and the data Data from the controller 2200, the semiconductor device 2300 stores the data Data therein. Furthermore, when the semiconductor device 2300 receives the read command RD CMD from the controller 2200, the semiconductor device 2300 transmits, to the controller 2200, the data Data that have been stored in the semiconductor device 2300.

In an embodiment, the semiconductor device 2300 includes control logic 2310 and a memory area 2320.

The control logic 2310 controls the memory area 2320 based on a command CMD that is received from the controller 2200. For example, when the command CMD is the write command WT CMD, the control logic 2310 stores received data in the memory area 2320. When the command CMD is the read command RD CMD, the control logic 2310 transmits, to the controller 2200, data stored in the memory area 2320.

Furthermore, the control logic 2310 stores the time when the write command WT CMD is received from the controller 2200 in the memory area 2320 as a write time stamp (WT time stamp). The control logic 2310 stores the time when the read command RD CMD is received from the controller 2200 in the memory area 2320 as a read time stamp (RD time stamp). In this case, the write time stamp (WT time stamp) and the read time stamp (RD time stamp) may be stored in a specific area 2321 of the memory area 2320.

The memory area 2320 includes a plurality of memory cells, for example. Therefore, the specific area 2321 also includes multiple memory cells, for example. In this case, as described above, the specific area 2321 of the memory area 2320 stores the write time stamp (WT time stamp) and the read time stamp (RD time stamp), and data Data received from the controller 2200 are stored in areas other than the specific area 2321 in the memory area 2320.

The semiconductor device 2300 performs a write operation for transitioning a state of a memory cell to one of a plurality of states based on a value of the data Data when receiving the write command WT CMD. When receiving the read command RD CMD, the semiconductor device 2300 determines the state of the memory cell, and transmits, to the controller 2200, the data Data corresponding to the determined state.

For example, the semiconductor device 2300 performs a write operation for transitioning a state of a memory cell to one of a set state and a reset state based on the value of the data Data received from the controller 2200. When receiving the read command RD CMD, the semiconductor device 2300 determines whether the state of the memory cell is the set state or the reset state, and transmits, to the controller 2200, the data Data corresponding to the determined state. In this case, a read voltage Vread may be used to determine whether the state of the memory cell is the set state or the reset state.

When receiving the read command RD CMD, the control logic 2310 receives the write time stamp (WT time stamp) and the read time stamp (RD time stamp) that have been stored in the specific area 2321 of the memory area 2320. Upon receiving the read command RD CMD, the control logic 2310 performs a read voltage (Vread) control operation, in which the control logic 2310 adjusts a level of the read voltage Vread based on the write time stamp (WT time stamp) and the read time stamp (RD time stamp). Thereafter, the semiconductor device 2300 determines states of memory cells in the memory area 2320 based on the read voltage Vread, and transmits the data Data corresponding to the determined states to the controller 2200.

In an embodiment, in the read voltage control operation, the control logic 2310 adjusts the level of the read voltage Vread based on an elapsed time from the reception of the write command WT CMD to the reception of a read command RD CMD, using the write time stamp (WT time stamp). In an embodiment, when the elapsed time is determined to be equal to or smaller than a critical time, the control logic 2310 adjusts the level of the read voltage Vread to be a target level. On the other hand, when the elapsed time is determined to exceed the critical time, the control logic 2310 adjusts the level of the read voltage Vread to be higher than the target level.

In another embodiment, the control logic 2310 adjusts the level of the read voltage Vread based on the read time stamp (RD time stamp). For example, the control logic 2310 adjusts the level of the read voltage Vread based on an elapsed time from the reception of a previous read command RD CMD to the reception of a current read command RD CMD, using the read time stamp (RD time stamp). The semiconductor device 2300 receives the current read command RD CMD after the previous read command RD CMD. In an embodiment, when the elapsed time is determined to be equal to or smaller than a critical time, the control logic 2310 adjusts the level of the read voltage

Vread to be a target level. On the other hand, when the elapsed time is determined to exceed the critical time, the control logic 2310 adjusts the level of the read voltage Vread to be higher than the target level.

As described above, when receiving the read command RD CMD, the control logic 2300 determines the level of the read voltage Vread based on the write time stamp (WT time stamp) and the read time stamp (RD time stamp). Accordingly, the semiconductor device 2300 determines states of memory cells in the memory area 2320 based on the read voltage Vread. In this case, the write time stamp (WT time stamp) and the read time stamp (RD time stamp) may be times stored for each address of a write operation or a read operation. Accordingly, the aforementioned operation of the semiconductor device 2300 may occur when a write operation and a read operation, or a previous read operation and a current read operation, are performed based on the same address.

The semiconductor system and the semiconductor device according to embodiments of the present disclosure have been described as technologies in which a level of a read voltage is adjusted by comparing an elapsed time between a write operation and a read operation or between a previous read operation and a current read operation with a critical time. However, the level of the read voltage may also be adjusted for each elapsed time by subdividing the critical time.

For example, the critical time may be subdivided into a first setting time and a second setting time longer than the first setting time. When the elapsed time is equal to or smaller than the first setting time, the read voltage may have a first level (or a target level). When the elapsed time is greater than the first setting time and equal to or smaller than the second setting time, the level of the read voltage may be adjusted to a second level. Furthermore, when the elapsed time is greater than the second setting time, the level of the read voltage may be adjusted to a third level. In this case, the first level may be the lowest level, and the third level may be the highest level. The second level may be between the first level and the third level.

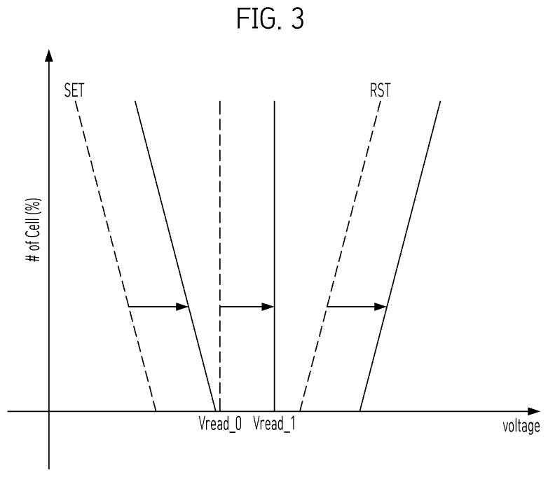

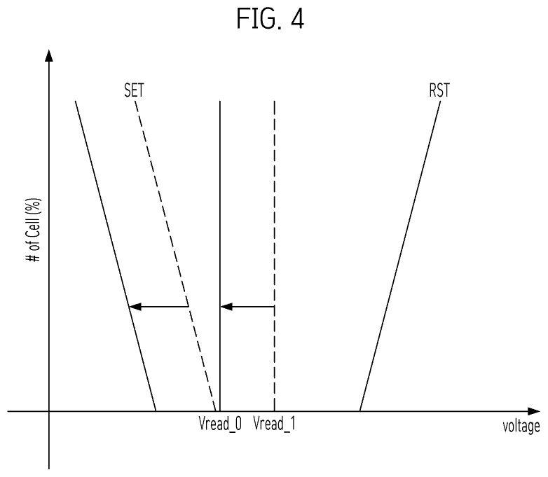

FIGS. 3 and 4 describe operations of a semiconductor device and a semiconductor system according to embodiments of the present disclosure.

FIG. 3 illustrates threshold voltages of a plurality of memory cells that are included in the memory area 2320 shown in FIG. 2. The plurality of memory cells store data Data in a set state SET or a reset state RST. The threshold voltage of each memory cell in the set state SET may be lower than the threshold voltage of each memory cell in the reset state RST. The level of the threshold voltage of each memory cell, whose state has been transitioned to the set state SET or the reset state RST by a write operation, may change over time.

Referring to FIG. 3, the level of the threshold voltage of the memory cell in the set state SET may be lower than the level of the threshold voltage of the memory cell in the reset state RST. In this case, to identify the state of the memory cell during a read operation, whether the memory cell is turned on or not may be determined by checking a center voltage level between the set state SET and reset state RST of the memory cell. This is achieved using a read voltage Vread_0 having a target level. For example, when the read voltage Vread_0 having the target level is provided to the memory cell, the memory cell in the set state SET is turned on because the level of the read voltage Vread_0 is higher than the level of the threshold voltage of the memory cell. On the other hand, when the read voltage Vread_0 having the target level is provided to the memory cell, the memory cell in the reset state RST is turned off because the level of the read voltage Vread_0 is lower than the level of the threshold voltage of the memory cell. The semiconductor device 2300 identifies states of memory cells based on the read voltage Vread_0 having the target level.

However, the level of the threshold voltage of each memory cell, which has been transitioned to the set state SET or the reset state RST by a write operation, may change over time. For example, the level of the threshold voltage of each memory cell in the set state SET or the reset state RST may increase over time.

If the level of the read voltage Vread is not adjusted, and the level of the threshold voltage of the memory cell in the set state SET becomes higher than the level of the read voltage Vread, the reliability of data storage may be reduced because the memory cell in the set state SET may be incorrectly identified as being in the reset state RST. Furthermore, if the read voltage Vread rises and thus the level of the read voltage Vread becomes close to the level of the threshold voltage of the memory cell in the reset state RST, the reliability of data storage may be reduced because the memory cell in the reset state RST is turned on and thus the memory cell may be incorrectly identified as being in the set state SET.

Accordingly, the semiconductor system 1000 illustrated in FIG. 1 and the semiconductor device 2300 illustrated in FIG. 2 each perform a read operation by adjusting the level of the read voltage Vread based on an elapsed time from a write operation to the read operation, when the read operation is performed after the write operation. For example, the semiconductor system 1000 and the semiconductor device 2300 each store the time when the write operation is performed, specifically the time when the write command WT CMD is received, as the write time stamp (WT time stamp). After that, when a read command RD CMD is received, they calculate an elapsed time from the write time stamp (WT time stamp) to the time when the read command RD CMD is received. Thereafter, the semiconductor system 1000 and the semiconductor device 2300 each compare the elapsed time with a critical time, and identify a state of a memory cell based on the read voltage Vread_0 having a target level when the elapsed time is equal to or smaller than the critical time. On the other hand, when the elapsed time is greater than the critical time, the semiconductor system 1000 and the semiconductor device 2300 each identify the state of the memory cell based on a read voltage Vread_1 higher than the read voltage Vread_0. The reliability of data storage can be improved by performing a read operation with the read voltage Vread whose level is adjusted according to the elapsed time.

FIG. 4 illustrates the change in threshold voltages of memory cells when a current read operation is performed after a previous read operation is performed on a memory cell whose threshold voltage level has increased over time.

Referring to FIG. 4, when the previous read operation is performed while levels of threshold voltages of memory cells in the set state SET and the reset state RST have increased over time since a write operation, the level of the threshold voltage of each memory cell that has been turned on and that is in the set state SET becomes a level of a threshold voltage transitioned to during the write operation. Consequently, the corresponding memory cell may remain in the set state SET. In other words, the level of the threshold voltage of each memory cell in the set state SET and turned on during the previous read operation may be lowered.

Accordingly, the semiconductor system 1000 and the semiconductor device 2300 each perform the current read operation by adjusting the level of the read voltage Vread based on an elapsed time since the previous read operation when the current read operation is performed after the previous read operation.

For example, the semiconductor system 1000 and the semiconductor device 2300 store the time when the previous read operation is performed, specifically the time when a previous read command RD CMD is received, as the read time stamp (RD time stamp). After that, when a read command RD CMD is received again, i.e., when a current read command RD CMD is received, an elapsed time from the read time stamp (RD time stamp) to the time when the current read command RD CMD is received is calculated. Thereafter, the semiconductor system 1000 and the semiconductor device 2300 each compare the elapsed time with a critical time, and identify a state of a memory cell based on the read voltage Vread_0 having a target level, when the elapsed time is equal to or smaller than the critical time. On the other hand, when the elapsed time is greater than the critical time, the semiconductor system 1000 and the semiconductor device 2300 each identify the state of the memory cell based on the read voltage Vread_1 higher than the read voltage Vread_0. Therefore, the reliability of data storage can be improved by performing a read operation with the read voltage Vread whose level is adjusted according to the elapsed time.

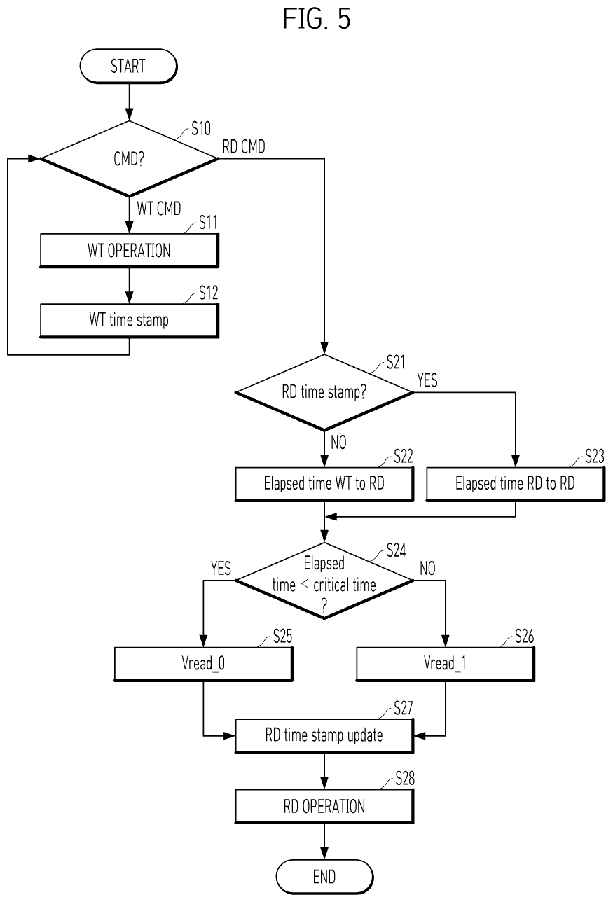

FIG. 5 is a flowchart for describing an operating method of a semiconductor system or a semiconductor device according to an embodiment of the present disclosure.

Referring to FIG. 5, the operating method includes a command determination process S10, a write operation process S11, a write time storage process S12, a read time check process S21, a first elapsed time calculation process S22, a second elapsed time calculation process S23, an elapsed time determination process S24, a first read voltage selection process S25, a second read voltage selection process S26, a read time storage process S27, and a read operation process S28.

In an embodiment, the command determination process S10 includes a process of determining whether a received command CMD is a write command WT CMD or a read command RD CMD. When the received command CMD is determined as the write command WT CMD in the command determination process S10, the write operation process S11 may be performed.

In an embodiment, the write operation process S11 includes a process of transitioning a state of a memory cell to a set state SET or a reset state RST based on a value of data. In this case, a level of a threshold voltage of a memory cell in the set state SET may be lower than a level of a threshold voltage of a memory cell in the reset state RST.

After the write operation process S11 is performed, the write time storage process S12 may be performed.

In an embodiment, the write time storage process S12 includes a process of storing the time when the write operation process S11 is performed as a write time stamp (WT time stamp) based on the write command WT CMD. In this case, the write time storage process S12 may be performed such that the write time stamp (WT time stamp) is stored in either the buffer memory 1300 shown in FIG. 1 or the specific area 2321 of the memory area 2320 shown in FIG. 2.

When the received command CMD is determined as the read command RD CMD in the command determination process S10, the read time check process S21 may be performed.

In an embodiment, the read time check process S21 includes a process of checking whether there is a stored read time stamp (RD time stamp). For example, the read time check process S21 may be a process of checking, by the controller 1200 shown in FIG. 1, whether there is a read time stamp (RD time stamp) stored in the buffer memory 1300, or may be a process of checking, by the control logic 2310 shown in FIG. 2, whether there is a read time stamp (RD time stamp) stored in the specific area 2321 of the memory area 2320.

When it is determined that there is no stored read time stamp (RD time stamp), the first elapsed time calculation process S22 may be performed.

In an embodiment, the first elapsed time calculation process S22 includes a process of calculating an elapsed time, based on the write time stamp (WT time stamp) stored in the write time storage process S12 and the time when the read command RD CMD determined in the command determination process S10 is received. For example, the first elapsed time calculation process S22 may be a process of calculating an elapsed time from the time (WT time stamp) when a write operation is performed to the time when the read command RD CMD is received.

When it is determined in the read time check process S21 that there is a stored read time stamp (RD time stamp), the second elapsed time calculation process S23 may be performed.

In an embodiment, the second elapsed time calculation process S23 includes a process of calculating an elapsed time based on the stored read time stamp (RD time stamp) and the time when the read command RD CMD determined in the command determination process S10 is received. For example, the second elapsed time calculation process S23 may calculate an elapsed time from the time (RD time stamp) when a previous read operation is performed to the time when a current read command RD CMD is received.

In an embodiment, the elapsed time determination process S24 includes a process of comparing the elapsed time that has been calculated in the first elapsed time calculation process S22 or the second elapsed time calculation process S23 with a critical time.

When the elapsed time is determined to be equal to or smaller than the critical time (YES), the first read voltage selection process S25 may be performed.

In an embodiment, the first read voltage selection process S25 includes a process of selecting the read voltage Vread_0 having a target level.

On the other hand, when the elapsed time is determined to be greater than the critical time (NO), the second read voltage selection process S26 may be performed.

In an embodiment, the second read voltage selection process S26 includes a process of selecting the read voltage Vread_1 having a level higher than the target level.

After the first read voltage selection process S25 or the second read voltage selection process S26 is performed, the read time storage process S27 may be performed.

In an embodiment, the read time storage process S27 includes a process of storing the time when a read operation is performed as the read time stamp (RD time stamp). If there is a stored read time stamp (RD time stamp), in the read time storage process S27, the stored read time stamp (RD time stamp) is updated with the time when the command CMD, which is determined as the read command RD CMD in the command determination process S10, is received.

After the read time storage process S27 is performed, the read operation process S28 checks a state of a memory cell based on the read voltage Vread_0 or Vread_1 that has been selected.

Although embodiments according to the technical spirit of the present disclosure have been described above with reference to the accompanying drawings, the embodiments have been provided to merely describe embodiments according to the concept of the present disclosure, and the present disclosure is not limited to the embodiments. A person having ordinary knowledge in the art to which the present disclosure pertains may substitute, modify, and change the embodiments in various ways without departing from the technical spirit of the present disclosure written in the claims. Such substitutions, modifications, and changes may be said to belong to the scope of the present disclosure.

What is claimed is:

1. An operating method of a semiconductor device, the method comprising:
checking whether there is a stored read time stamp upon receiving a read command;
calculating an elapsed time based on the stored read time stamp and a time when the read command is received, the stored read time stamp corresponding to a time when a previous read operation is performed;
comparing the elapsed time with a first setting time;
selecting a read voltage having a first level instead of a target level when the elapsed time is greater than the first setting time; and
performing a read operation using the selected read voltage.

2. The operating method of claim 1, wherein the first level is higher than the target level.

3. The operating method of claim 1, further comprising storing a time when the read operation is performed as a read time stamp.

4. The operating method of claim 1, further comprising selecting the read voltage having the target level when the elapsed time is equal to or smaller than the first setting time.

5. The operating method of claim 3, wherein the read time stamp is stored in a specific area of a memory area in the semiconductor device.

6. The operating method of claim 1, further comprising calculating an elapsed time based on a write time stamp and a time when the read command is received, when there is no stored read time stamp, the write time stamp corresponding to a time when a write operation is performed, the read operation following the write operation.

7. The operating method of claim 6, wherein the write time stamp corresponds to a time when a write operation is performed before receiving the read command.

8. The operating method of claim 1, further comprising selecting a read voltage having a second level different from the first level, when the elapsed time is greater than a second setting time.

9. The operating method of claim 8, wherein
the second setting time is longer than the first setting time, and
the second level is higher than the first level.

10. A semiconductor device, comprising:
a memory area comprising a plurality of memory cells; and
control logic configured to perform a write operation of storing data in the memory area or a read operation of outputting data stored in the memory area, in response to a command,
wherein times when the write operation and the read operation are performed are stored as a write time stamp and a read time stamp in a specific area of the memory area under a control of the control logic.

11. The semiconductor device of claim 10, wherein when the command is a read command, the control logic adjusts a level of a read voltage based on the write time stamp or the read time stamp.

12. The semiconductor device of claim 11, wherein the control logic adjusts the level of the read voltage based on the write time stamp if there is no stored read time stamp.

13. The semiconductor device of claim 12, wherein the control logic adjusts the level of the read voltage by comparing an elapsed time from the write time stamp to a time when the read command is received with a critical time.

14. The semiconductor device of claim 13, wherein the control logic is configured to:
select a read voltage having a target level when the elapsed time is equal to or smaller than the critical time; and
select a read voltage having a level higher than the target level when the elapsed time is greater than the critical time.

15. The semiconductor device of claim 11, wherein the control logic adjusts the level of the read voltage based on the read time stamp if there is a stored read time stamp.

16. The semiconductor device of claim 15, wherein the control logic adjusts the level of the read voltage by comparing an elapsed time from the stored read time stamp to a time when the read command is received with a critical time.

17. The semiconductor device of claim 16, wherein the control logic is configured to:
select a read voltage having a target level when the elapsed time is equal to or smaller than the critical time; and
select a read voltage having a level higher than the target level when the elapsed time is greater than the critical time.

18. A semiconductor system, comprising:
a controller configured to provide a read command or a write command based on a request from a host;
a buffer memory configured to store a time when the read command or the write command is provided as a read time stamp or a write time stamp, respectively and configured to provide the stored time stamp to the controller upon receiving the read command; and
a semiconductor device configured to store data or output data stored in the semiconductor device, based on the read command or the write command.

19. The semiconductor system of claim 18, wherein when providing the read command to the semiconductor device, the controller is configured to:
determine a level of a read voltage based on the stored time stamp provided by the buffer memory, and
provide the semiconductor device with the read voltage along with the read command.

20. The semiconductor system of claim 18, wherein when the stored time stamp provided by the buffer memory is the write time stamp, the controller is configured to:
calculate an elapsed time from the write time stamp to a time when the read command is provided; and
determine a level of a read voltage based on the elapsed time.

21. The semiconductor system of claim 20, wherein the controller determines the level of the read voltage to be higher than a target level when the elapsed time is greater than a critical time.

22. The semiconductor system of claim 18, wherein when the stored time stamp provided by the buffer memory is the read time stamp, the controller is configured to:
calculate an elapsed time from the read time stamp to the time when the read command is provided; and
determine a level of a read voltage based on the elapsed time.

23. The semiconductor system of claim 22, wherein the controller determines the level of the read voltage to be higher than a target level when the elapsed time is greater than a critical time.
